(19) United States
(12) Patent Application Publication
(10) Pub. No.: US 2006/0232298 A1
(43) Pub. Date: Oct. 19, 2006

(54) Signal issuing unit

(75) Inventors: Stephan Konrad, Rieden (DE); Thomas Haerle, Marktoberdorf (DE)

Correspondence Address: BACON & THOMAS, PLLC, 625 SLATERS LANE, FOURTH FLOOR, ALEXANDRIA, VA, 22314, US

(73) Assignee: Endress + Hauser Wetzer GmbH + Co. KG, Nesselwang (DE)

(21) Appl. No.: 11/372,110

(22) Filed: Mar. 10, 2006

(30) Foreign Application Priority Data
Mar. 10, 2005 (DE) 102005011512.8

(51) Int. Cl. H03K 19/084

(52) U.S. Cl. 326/106

(57) ABSTRACT

A signal issuing unit for issuance of at least one electrical output signal. The signal issuing unit includes: At least one contact unit, which is embodied in such a manner that a digital electrical signal or an analog electrical signal can be issued by way of it; at least one multiplexer unit, which is embodied in such a manner that it transfers the electrical output signal onto the at least one contact unit; and at least one control unit for control of the multiplexer unit. Additionally, the invention relates to a measuring device having a signal issuing unit of the invention.

The invention relates to a signal issuing unit for the issuance of at least electrical output signal. Additionally, the invention relates to a measuring device having the signal issuing unit of the invention. In the case of the measuring device, such can be a measuring device for determining and/or monitoring physical or chemical variables, such as temperature, fill level, flow, pH-value, electrical conductivity, density or viscosity.

A measuring device can forward the measured value in analog manner or digitally; in the present case, of concern most often is the state of a switch, i.e. whether a limit value has been reached, or not. Devices of the state of the art utilize predefined switch outputs. This means that an output is operated either in analog manner or as a switch output. Consequently, the function of the signal output, as well as its position at the plug contact is fixedly predetermined. Furthermore, the manufacturer must react on the basis of the different requirements on the customer-side with correspondingly many variants of the product. Therefore, for the different applications and requirements and for the retirement of old devices, also correspondingly many variants of the device have to be kept in stock.

Consequently, it is an object of the invention to provide a signal issuing device, which is universally applicable for different requirements.

The object is achieved by the invention with a signal issuing device for the issuance of at least one electrical output signal. Such signal issuing device includes: At least one contact unit, which is embodied in such a manner that it can issue a digital electrical signal or an analog electrical signal; at least one multiplexer unit, which is embodied in such a manner that it transfers the electrical output signal to the at least one contact unit; and at least one control unit for controlling the multiplexer unit. In the signal issuing unit, there is, thus, at least one contact unit (thus the electrical, individual contact, blade or pin of a plug), which can carry an analog signal or a digital signal. In the case of a digital signal, or switch signal, of concern is, for example, an on/off signal, or “limit value reached”, or “limit value subceeded, or fallen beneath”, as the case may be. The actual output signal is sent to the contact unit via the multiplexer. Depending on the requirements, it is also possible, that an appropriate analog/digital converter, or a digital/analog converter is provided, when an analog signal needs to be output digitally, or when a digital signal needs to be output in analog form. The required conversion can, however, already be done before the signal issuing unit, so that this always receives the signal which needs to be issued. Especially, it is provided that either an analog signal is sent to the contact unit, or that the contact unit is connected to the appropriate digital signal, or switch signal. The control unit controls the multiplexer and controls, in this way, the issuance of the output signal. The control unit can, in such case, be adjusted in the context of the manufacturing, so that a defined signal issue constellation is delivered, or an input unit can be provided, via which the desired signal issue configuration can be brought about on-site, so that the signal issuing unit retains its universal applicability. Via this signal issuing unit of the invention, the device connected therewith can, thus, be so adjusted, that it is matched to the application or requirements.

An embodiment of the signal issuing unit of the invention includes, that at least two contact units are provided, and that the multiplexer unit is embodied in such a manner that it transfers the electrical output signal to at least one of the at least two contact units. If, thus, on the receiving-side, the output signal is expected on the first contact unit, then this information is stored in the control unit, and the control unit controls the multiplexer in such a manner that the output signal is applied to the first contact unit. Corresponding behavior occurs, when the output signal is expected on the second contact unit. Extension to arbitrarily many contact units, or pins, is likewise possible. There exists, consequently, the choice between an analog and a digital issuance of the output signal on at least one of the present contact units.

An embodiment of the signal issuing unit provides that at least one input unit is provided, with the input unit being embodied in such a manner that, by way of it, information can be input concerning onto which contact unit the electrical output signal is to be transferred by the multiplexer unit. This input unit can be implemented, for example, by DIP-switches. The input unit thus makes possible the adapting of the signal issuing unit on-site and in conformance with the existing conditions, or requirements, as the case may be.

The invention relates, furthermore, to a measuring device having at least one signal issuing unit according to at least one of the above embodiments of the signal issuing unit. Such a measuring device of the invention simplifies manufacture and, above all, a device variation permits the fulfillment of a multiplicity of demands on the signal output.

The invention will now be explained in greater detail on the basis of the appended drawings, the figures of which show as follows:

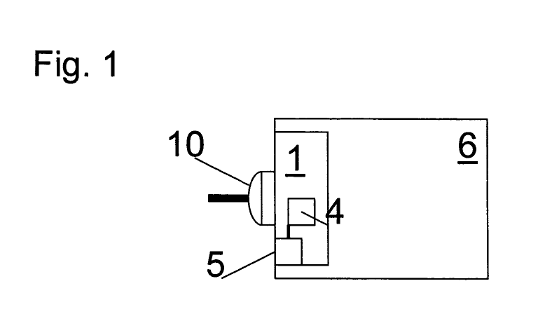

FIG. 1 a measuring device having the signal issuing unit; and

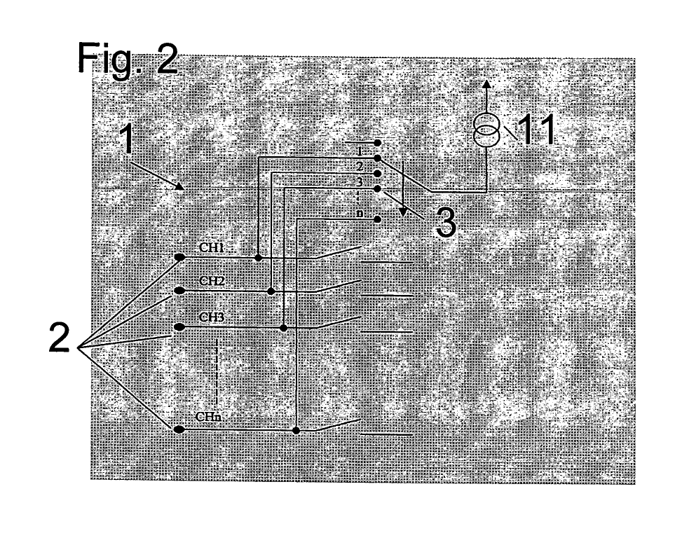

FIG. 2 an embodiment of the signal issuing unit.

FIG. 1 shows a measuring device 6, involving, for example, a temperature sensor. This measuring device 6 produces an output signal related to the measured variable, temperature. For issuing the output signal, the signal issuing unit 1 of the invention is provided. Via this, it is possible to issue the output signal via the blades, pins or contact units 2 in such a manner that the output signal can be received there by the receiving unit 10, i.e. first by the jack of the plug of the measuring device, where the suitable tapping locations are provided in the receiving unit 10 therefor. An advantage of this signal issuing unit 1 is, thus, that the issuance is so adapted as the demands of the receiving-side require. Assumed, however, is that the signal issuing unit 1 and the receiving unit 10 are embodied to fit geometrically. The measuring device 6 connected with the signal issuing unit 1 includes, consequently, in itself, a multiplicity of signal issuing variants, which, without the invention, would have to be realized in different types of construction. How the signal issuing unit 1 is to be actuated is, here, predetermined by the input unit 5. For this purpose, for example, DIP-switches can be provided. Via these, it is input, at which contact unit the issued signal should be applied. This is then implemented via the control unit 4, which is, here, directly connected with the input unit 5. The control unit 4 is additionally connected with the multiplexer unit 3 and controls such.

FIG. 2 presents a concrete embodiment of a signal issuing unit 1 of the invention. Present here are n contact units 2: CH1, CH2, . . . , CHn. These are engaged via the multiplexer unit, which is connected with the control unit 4 (not shown in FIG. 2). Via the multiplexer unit 3, for example, contact with the current source 11, e.g. 4 . . . 20 mA, can be directly produced, when the fitting contact unit 2 is to issue an analog signal. In the case of the 4 . . . 20 mA-signals, the output signal is thus a current signal of a appropriate signal strength. The uppermost setting, with which the multiplexer unit 3 can connect the contact unit 2, means, that no analog signal is to be issued. In this case, the contact units 2 are connected corresponding to the digital switch-states (here illustrated by the horizontal lines below the multiplexer unit 3).

### LIST OF REFERENCE CHARACTERS

1 signal issuing unit
2 contact unit
3 multiplexer unit
4 control unit
5 input unit
6 measuring device
10 receiving unit
11 current source

1-4. (canceled)

5. A signal issuing unit for issuance of at least one electrical output signal, comprising:
at least one contact unit, which is embodied in such a manner that it can issue a digital electrical signal or an analog electrical signal;
at least one multiplexer unit, which is embodied in such a manner that it transfers the electrical output signal onto said least one contact unit; and
at least one control unit for controlling said at least one multiplexer unit.

6. The signal issuing unit as claimed in claim 5, wherein:
at least two contact units are provided; and
said at least one multiplexer unit is embodied in such a manner that it transfers the electrical output signal onto at least one of said at least two contact units.

7. The signal issuing unit as claimed in claim 6, wherein:
at least one input unit is provided, which is embodied in such a manner that it enables input of which contact unit the electrical output signal is to be transferred to by said at least one multiplexer unit.

8. The measuring device having at least one signal issuing unit comprising at least one contact unit, which is embodied in such a manner that it can issue a digital electrical signal or an analog electrical signal;
at least one multiplexer unit, which is embodied in such a manner that it transfers the electrical output signal onto said least one contact unit; and
at least one control unit for controlling said at least one multiplexer unit.
